(19) United States
(12) Patent Application Publication
(10) Pub. No.: US 2011/0198617 A1
(43) Pub. Date: Aug. 18, 2011

(54) ELECTRODE, SEMICONDUCTOR DEVICE, AND METHOD FOR MANUFACTURING THE SEMICONDUCTOR DEVICE

(75) Inventors: Kensuke Iwanaga, Saitama (JP); Seiichi Yokoyama, Saitama (JP); Hideki Hashimoto, Saitama (JP); Kenichi Nonaka, Saitama (JP); Masashi Sato, Saitama (JP); Norio Tsuyuguchi, Saitama (JP)

(73) Assignees: HONDA MOTOR CO., LTD., Tokyo (JP); SHINDENGEN ELECTRIC MANUFACTURING CO., LTD., Tokyo (JP)

(21) Appl. No.: 13/125,187

(22) PCT Filed: Oct. 6, 2009
(86) PCT No.: PCT/JP2009/067389

§ 371 Date: Apr. 20, 2011

(30) Foreign Application Priority Data
Oct. 23, 2008 (JP) 2008-273319

(51) Int. Cl. H01L 29/20; H01L 21/283; B82Y 99/00; B82Y 40/00

(52) U.S. Cl. 257/77; 438/656; 977/755; 977/890; 257/E29.089; 257/E21.159

(57) ABSTRACT

Disclosed is a semiconductor device comprising a p-type SiC semiconductor and an ohmic electrode having an Ni/Al laminated structure provided on the p-type SiC semiconductor. The semiconductor device simultaneously has improved contact resistance and surface roughness in the ohmic electrode. The semiconductor device comprises an ohmic electrode (18) comprising a nickel (Ni) layer (21), a titanium (Ti) layer (22), and an aluminum (Al) layer (23) stacked in that order on a p-type silicon carbide semiconductor region (13). The ohmic electrode (18) comprises 14 to 47 atomic % of a nickel element, 5 to 12 atomic % of titanium element, and 35 to 74 atomic % of an aluminum element, provided that the atomic ratio of the nickel element to the titanium element is 1 to 11.

### TECHNICAL FIELD

The present invention relates to an electrode wherein an ohmic electrode is improved in both contact resistance and surface roughness, to a semiconductor device and to a method for manufacturing the semiconductor device.

### BACKGROUND ART

Improving the efficiency of the flow of electric current through ohmic electrodes, in which the current and voltage are in a proportional relationship with each other, in semiconductor devices employing silicon carbide semiconductors (referred to as “SiC semiconductors” or “SiC”) is an important technological issue. Reducing the contact resistance between the electrode and the semiconductor interface is important for increasing the efficiency in ohmic electrodes. On the other hand, increasing the surface roughness (degree of roughness on the surface) of the electrode surface is also important for making the device characteristics uniform and improving the yield rate. Better contact is produced with reduced roughness of the surface, as expressed by the surface roughness of the electrode. Conventional techniques relating to ohmic electrodes are disclosed in Patent Literature 1 and 2.

The method for forming a p-type SiC electrode described in Patent Literature 1 is one in which an ohmic electrode is formed, and is a technique for forming an electrode having an Ni/Ti/Al laminated structure on an SiC semiconductor. The object of this method is to reduce the contact resistance of the ohmic electrode. According to the electrode-forming method, the Ni/Ti/Al laminated electrode is heat-treated in an inactive gas at 900 to 1000° C. for 5 to 10 minutes. The contact resistance between the p-type SiC semiconductor and the ohmic electrode can thereby be reduced, and uniform ohmic characteristics can be obtained within the electrode.

The SiC electrode and the method for manufacturing the electrode described in Patent Literature 2 allow both the contact properties and the surface morphology (flatness) of the ohmic electrode to be simultaneously improved. The Ni/Ti/Al laminated electrode is heat-treated in a vacuum at 800 to 1000° C. for 5 to 10 minutes. The contact resistance between the p-type SiC semiconductor and the electrode can thereby be reduced.

The composition ratios of Ni, Ti, and Al in the conventional techniques described in Patent Literature 1 and 2 are shown in FIG. 3, in which the Ti ratio is set to 1 according to Table 2. The composition ratio of Al and Ni in Patent Literature 1 is high, and the composition ratio of Ni in Patent Literature 2 is extremely low. It is believed that the conventional techniques improve the contact resistance of an ohmic electrode having an Ni/Ti/Al laminated structure formed on a p-type SiC semiconductor. However, problems arise concerning the generation of unevenness on the electrode surface (increase of surface roughness) when film formation conditions are improperly changed. Specifically, the metals tend to aggregate and the surface roughness of the electrode increases during heat treatment because the composition ratio of Al and Ni is high in the technique described in Patent Literature 1. In addition, the flatness of the electrode surface is outlined in the technique described in Patent Literature 2, but no specific examples or specific numerical values are given concerning the flatness, and there is the possibility that the flatness can be further improved.

A problem usually arose in which the surface roughness increased due to elements aggregating together when the amount of elements added was increased in an attempt to reduce the contact resistance of an ohmic electrode obtained using an Ni/Ti/Al laminated structure and formed on an SiC semiconductor. Conversely, a problem arose in which the content of the metallic element used as the electrode was reduced and the contact resistance was increased when the amount of elements added was reduced in an attempt to reduce the surface roughness. In this case, another problem was created in which the durability of the electrode was also reduced. Simultaneously reducing contact resistance and improving surface roughness could not be accomplished in Patent Literature 1 and 2.

### PRIOR ART LITERATURE

### Patent Literature

Patent Literature 1: Japanese Patent No. 2940699

Patent Literature 2: Japanese Patent No. 4026339

### SUMMARY OF INVENTION

### Technical Problem

In view of the aforementioned problem, an object of the present invention is to provide a semiconductor device in which an ohmic electrode having an Ni/Ti/Al laminated structure is formed on a p-type SiC semiconductor, and to provide the ohmic electrode and a method for manufacturing the semiconductor device wherein the contact resistance and surface roughness of the ohmic electrode can be simultaneously improved.

### Solution to Problem

According to a first aspect of the present invention, there is provided a semiconductor device comprising: a p-type silicon carbide semiconductor region; and an ohmic electrode including a nickel layer, a titanium layer, and an aluminum layer stacked in that order on the p-type silicon carbide semiconductor region, wherein the ohmic electrode includes 14 to 47 atomic % of a nickel element, 5 to 12% of a titanium element, and 35 to 74% of an aluminum element, and the atomic ratio of the nickel element to the titanium element is from 1 to 11.

Preferably, the ohmic electrode has an atomic ratio of the nickel element to the aluminum element of from 0.5 to 1.7 when the atomic ratio of the aluminum element to the titanium element is 6.3.

Desirably, a laminated film including the nickel layer, the titanium layer, and the aluminum layer in the ohmic electrode has a film thickness of 45 to 690 nm.

In a preferred form, the nickel layer, the titanium layer, and the aluminum layer in the ohmic electrode have a film thickness of 10 to 340 nm, 5 to 50 nm, and 30 to 300 nm, respectively.

Another ohmic electrode may be formed on a surface of the silicon carbide semiconductor region that is opposite a surface of the silicon carbide semiconductor region that includes the ohmic electrode.

According to another aspect of the present invention, there is provided a method for manufacturing a semiconductor device having an ohmic electrode that includes a nickel layer, a titanium layer, and an aluminum layer on a p-type silicon carbide semiconductor region, which method comprises the steps of: forming the nickel layer on the silicon carbide semiconductor region; forming the titanium layer on the nickel layer; forming the aluminum layer on the titanium layer; and forming the ohmic electrode by heating a laminated electrode body having the nickel layer, the titanium layer, and the aluminum layer at 600 to 850° C., wherein the ohmic electrode has an atomic ratio of the nickel element to the titanium element of from 1 to 11.

According to a further aspect of the present invention, there is provided an ohmic electrode which comprises: a nickel layer; a titanium layer; and an aluminum layer stacked in that order on a p-type silicon carbide semiconductor region, wherein the electrode includes 14 to 47 atomic % of a nickel element, 5 to 12% of a titanium element, and 35 to 74% of an aluminum element, and the atomic ratio of the nickel element to the titanium element is from 1 to 11.

### ADVANTAGEOUS EFFECTS OF INVENTION

The electrode and the semiconductor device according to the present invention have an ohmic electrode in which Ni, Ti, and Al are stacked in that order on a p-type SiC semiconductor region, and the ohmic electrode includes 14 to 47 atomic % of a nickel element, 5 to 12% of a titanium element, and 35 to 74% of an aluminum element, provided that the atomic ratio of the nickel element to the titanium element is from 1 to 11. Therefore, the surface roughness can be reduced without increasing the contact resistance of the ohmic electrode. In particular, the contact resistance of the ohmic electrode can be lowered and the surface roughness can be reduced using the atomic number and composition, rather than the film thickness, of the Ni/Ti/Al laminated electrode. The area of contact between the ohmic electrode and the SiC semiconductor can therefore be increased as well, the variability of the contact resistance can be suppressed, and the durability of the electrode can be increased.

In addition, the method for manufacturing a semiconductor device according to the present invention allows a semiconductor device aimed at achieving the above-described effect to be manufactured at a low cost by a simple process.

### BRIEF DESCRIPTION OF DRAWINGS

FIG. 1 is a flowchart illustrating a method for manufacturing an electrode and a semiconductor device according to an embodiment of the present invention;

FIG. 2 is a partial longitudinal sectional view showing device configurations and other aspects that correspond to each step of the method for manufacturing the electrode and the semiconductor device according to the present embodiment;

FIG. 3 is a graph showing the characteristics of an atomic % ratio relating Ti, Al/Ti, and Ni/Ti in Embodiments 1 to 5 of the present invention and Comparative Examples 1 to 5;

FIG. 4 is a graph showing the characteristics of surface roughness and contact resistance in Comparative example 5 when the atomic % ratio of Ni/Ti is within a range of 0 to 12; and

FIG. 5 is a graph showing the characteristics of an ohmic electrode according to the present invention.

### DESCRIPTION OF EMBODIMENTS

Certain preferred embodiments of the present invention are described below with reference to the accompanying drawings.

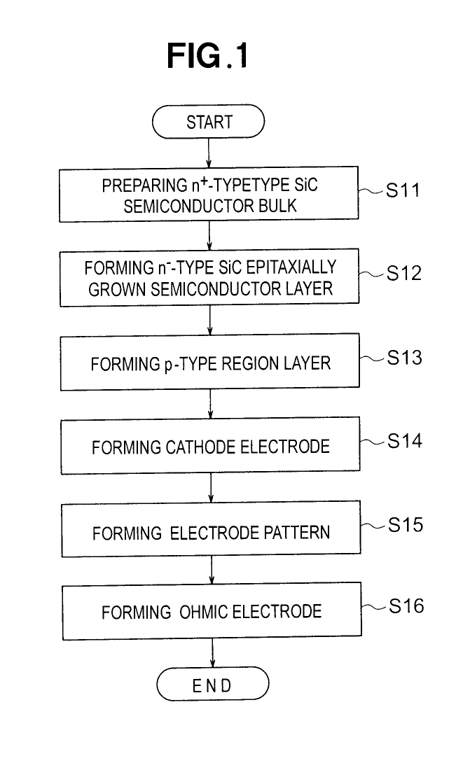

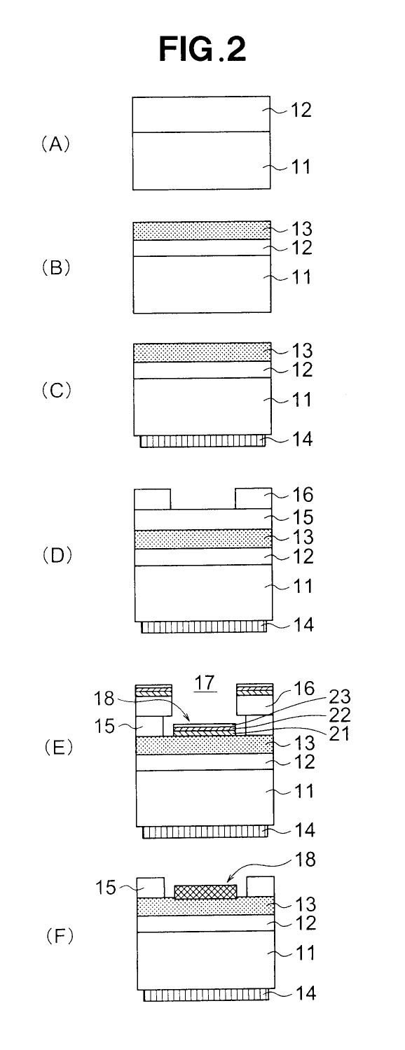

Referring now to FIGS. 1 and 2, description will be made as to an electrode and a method for manufacturing a semiconductor device provided with the electrode, according to an embodiment of the present invention. The semiconductor device has a p-type SiC semiconductor region. The method for manufacturing the electrode and the semiconductor device, and the configuration thereof are described with reference to FIGS. 1 and 2. FIG. 1 is a flowchart showing each step of the manufacturing method. FIG. 2 is a longitudinal sectional view showing cross-sectional structures (A) to (F) of the electrode and the semiconductor device produced by each of the steps.

The method for manufacturing the electrode and the like includes the following steps (1) to (6) (steps S11 to S16). The steps are performed in order from step S11 to step S16, as shown in FIG. 1.

(1) preparing an n⁺-type SiC semiconductor bulk (substrate base) (step S11)

(2) forming an n⁻-type SiC epitaxially grown semiconductor layer (step S12)

(3) forming a p-type region layer (step S13)

(4) forming a cathode electrode (step S14)

(5) forming an electrode pattern (step S15)

(6) forming an ohmic electrode (step S16)

The substrate configuration shown in (A) of FIG. 2 is formed by performing steps S11 and S12.

An n⁺-type SiC semiconductor bulk 11 is prepared in step S11, which is the step of preparing a substrate. “4H—SiC (0001) 8° off” or another such material is used for the substrate material ((A) of FIG. 2). The SiC semiconductor bulk 11 is also the cathode region of the semiconductor device. The SiC semiconductor bulk 11 has a thickness of, for example, about 340 μm, and an impurity concentration of, for example, about 1×10¹⁸ cm⁻³.

An SiC epitaxially grown semiconductor layer 12 is formed on the n⁺-type SiC semiconductor bulk 11 by epitaxy ((A) of FIG. 2) in the step of forming an n⁻-type SiC epitaxially grown semiconductor layer (step S12). The SiC epitaxially grown semiconductor layer 12 has a thickness of, for example, 20 μm, and is grown while being doped with nitrogen or the like in a concentration of 5×10¹⁵ cm⁻³ as an impurity.

Al ion implantation, activation annealing, and sacrificial oxidation treatments are performed sequentially in the step of forming a p-type region layer (step S13). As a result, a p-type region layer (p-type SiC region) 13 is formed on the upper surface portion of the SiC epitaxially grown semiconductor layer 12 ((B) of FIG. 2).

In the Al ion implantation treatment, the aluminum (Al) ions are implanted to a depth of, for example, about 2 μm, the ion implantation concentration is, for example, about 1×10¹⁹ cm⁻³, and the ambient temperature necessary for ion implantation is 600° C.

In the activation annealing heat treatment, the implanted ions are electrically activated inside the SiC epitaxially grown semiconductor layer 12 after ion implantation, and a heat treatment is performed in order to remove crystal defects generated by the ion implantation. An induction heat treatment furnace or the like is used in the activation annealing treatment, and the heat treatment is performed at, for example, a high temperature of about 1850° C. for about 10 minutes. Argon gas (Ar) may, for example, be used as the ambient gas, or a vacuum may be used.

A deactivation treatment is performed on the SiC surface of an uppermost part of the semiconductor device shown in (B) of FIG. 2. Sacrificial oxidation is performed in the deactivation treatment on the SiC surface. In the sacrificial oxidation treatment, an oxidation treatment is performed for 20 hours in, for example, a temperature environment of 1100° C. to form a sacrificial oxide film on the SiC surface. The sacrificial oxide film is then removed using hydrofluoric acid or the like.

In the step of forming a cathode electrode (step S14), a membranous cathode electrode 14 is formed on a lower surface of the SiC semiconductor bulk 11, which is the cathode region in the semiconductor device, using nickel (Ni) ((C) of FIG. 2). The cathode electrode 14 has a film thickness of, for example, about 200 nm. In the step of forming the cathode electrode 14, the film of the cathode electrode 14 is formed, and is then heated inside a furnace in order to perform annealing. The atmosphere inside the furnace is a vacuum. The cathode electrode 14 is annealed inside the furnace at a temperature of, for example, about 600 to 850° C., and is heated for about 30 minutes. The cathode electrode 14 is thus provided to the lower surface of the semiconductor device.

The step of forming an electrode pattern (step S15) is performed next. An interlayer film (insulating film) 15 is first formed during the formation of the electrode pattern ((D) of FIG. 2). A silicon dioxide film or the like is formed as the interlayer film 15 by CVD. The interlayer film 15 is a PSG film (a silicon dioxide film (phosphosilicate-glass) that includes P (phosphorous)) and has a thickness of, for example, about 500 nm. A patterned photoresist 16 is formed on the interlayer film 15 ((D) of FIG. 2). In the process, the photoresist 16 is formed over the entire surface of the interlayer film 15, and a predetermined pattern is then formed by etching. The predetermined pattern is a photoresist pattern for creating a location in which the below-described ohmic electrode is formed.

In the step of forming the ohmic electrode (step S16), an empty space 17 is first formed by etching, and an upper surface of the p-type region layer 13 is exposed in the aforementioned state shown in (D) of FIG. 2. A nickel element (Ni), a titanium element (Ti), and an aluminum element (Al) are then stacked sequentially on the p-type region layer 13 in the empty space 17 using vapor deposition, spattering, or another film-forming technique to form a laminated electrode body 18 ((E) of FIG. 2). The laminated electrode body 18 includes a nickel (Ni) layer 21, a titanium (Ti) layer 22, and an aluminum (Al) layer 23 stacked in that order. The Ni layer 21 has a film thickness of, for example, about 100 nm (=1000 Å), the Ti layer 22 about 25 nm (=250 Å), and the Al layer 23 about 150 nm (=1500 Å). The laminated structure of the Ni/Ti/Al layers is also formed on electrode portions other than the primary electrode portion, and the unnecessary films, other resist portions, and the like are therefore subjected to liftoff to be peeled off and removed ((F) of FIG. 2).

An annealing treatment is then performed in the furnace. Annealing is performed at a temperature of, for example, about 600 to 850° C. for a time of about 5 minutes. The furnace atmosphere is argon gas (Ar) and includes 2% of hydrogen gas (H₂). The laminated electrode body 18 having a laminated structure that includes the Ni layer 21, Ti layer 22, and Al layer 23 is ultimately formed as an ohmic electrode by the aforementioned annealing treatment.

In the method for manufacturing the electrode and the semiconductor device, the ohmic electrode 18 that includes the Ni layer 21, the Ti layer 22, and the Al layer 23 preferably has a composition ratio of 14 to 47 atomic % of the Ni element (atoms), 5 to 12 atomic % of the Ti element (atoms), and 35 to 74 atomic % of the Al element (atoms), provided that the atomic ratio of the Ni element to the Ti element is from 1 to 11.

Also, the ohmic electrode 18 preferably has an atomic ratio of the Ni element to the Al element of from 0.5 to 1.7 when the atomic ratio of the Al element to the Ti element is 6.3.

The entire laminated film of the ohmic electrode 18 preferably has a film thickness within a range of 45 to 690 nm. The Ni layer 21, Ti layer 22, and Al layer 23 preferably have film thicknesses within a range of 10 to 340 nm, 5 to 50 nm, and 30 to 300 nm, respectively.

In the step of forming the cathode electrode (step S14) described above, the cathode electrode 14 was formed on the lower surface of the SiC semiconductor bulk 11 using Ni, but the cathode electrode 14 is also an electrode having ohmic properties.

The method for determining the composition ratio will now be described. The composition ratio is computed based on the “atomic %” ratio. A calculation example of the composition ratio is shown in Table 1 below. Here, the atomic weight, density, film thickness, mass, weight %, atomic number, atomic %, and composition ratio (three ways) are shown for the Ni element, Ti element, and Al element.

TABLE 1
Calculation Example

| | Ni | Ti | Al | |
|---|---|---|---|---|
| Atomic weight | 58.69 | 47.9 | 26.97 | |
| Density | 8.9 | 4.54 | 2.699 | g/cm³ |
| Film thickness | 1000 | 250 | 1500 | Å |
| | 1.00E−05 | 2.50E−06 | 1.50E−05 | cm |
| Mass | 8.90E−05 | 1.14E−05 | 4.05E−05 | g |
| | | | | total 1.41E−04 g |
| Weight % | 6.32E+01 | 8.06E+00 | 2.87E+01 | % |
| Atomic number | 1.08E+00 | 1.68E−01 | 1.07E+00 | *6.02E23 |
| | | | | total 2.31E+00 *6.02E23 |
| Atomic % | 46.60 | 7.28 | 46.12 | % |
| Composition ratio | 6.399787 | 1 | 6.335091 | |
| | 1.010212 | 0.157851 | 1 | |
| | 1 | 0.156255 | 0.989891 | |

The method for calculating the composition ratio is based on the sequence of the following steps (1) to (5).

(1) Set the Parameters to be Used

The parameters to be used are atomic weight, density, and film thickness.

(2) Compute the Mass of Each of the Elements

The mass is determined based on the formula “film thickness×density=mass.”

(3) Compute the Weight % of Each of the Elements

The weight % is determined based on the formula “(mass of each element÷mass of the total)×100=weight %.”

(4) Compute the Atomic Number of Each of the Elements

The atomic number is determined based on the formula “(weight %×6.02E23)÷atomic weight=atomic number.”

(5) Compute the Atomic %

The atomic % is determined based on the formula “(atomic number of each element÷atomic number of the total)×100=atomic %.”

The ohmic electrode 18 according to the present embodiment or invention and the electrodes disclosed in Patent Literature 1 and 2, which were described in the “Background Art” section, are compared with each other in terms of “film thickness,” “atomic %,” “atomic % ratio,” and “characteristics” on the basis of the above-described method for calculating the composition ratio. These comparisons are shown in Table 2 below. “Contact resistance value (ρ_{c}: Ωcm²)” and “degree of surface unevenness (surface roughness)” are shown as the “characteristics.”

TABLE 2
Comparison of atomic % and composition ratio of each element

| | | Film | | | | | | | | | |
|---|---|---|---|---|---|---|---|---|---|---|---|
| | | Thickness | | | | Atomic % Ratio | | | Characteristics | | |
| | | (nm) | Atomic % | | | Ni/ | Al/ | Ni/ | Contact | Surface | |
| | | Ni/Ti/Al | Ni | Ti | Al | Al | Ti | Ti | resistance | roughness | |
| Present | Emb. 1 | 168/25/150 | 60 | 5 | 35 | 1.7 | 6.3 | 11 | 8.0E−4 | 50 | nm |
| Invention | Emb. 2 | 118/25/150 | 51 | 7 | 42 | 1.2 | 6.3 | 7.5 | 1.4E−4 | 150 | nm |
| | Emb. 3 | 100/25/150 | 47 | 7 | 46 | 1.0 | 6.3 | 6.4 | <1.0E−4 | 150 | nm |
| | Emb. 4 | 90/25/150 | 44 | 8 | 48 | 0.9 | 6.3 | 5.7 | 1.4E−4 | 150 | nm |
| | Emb. 5 | 68/25/150 | 37 | 9 | 54 | 0.7 | 6.3 | 4.4 | 8.0E−4 | 150 | nm |
| Patent | Comp. Ex. 1 | 18/25/150 | 14 | 12 | 74 | 0.2 | 6.3 | 1.1 | 2.0E−3 | 1000 | nm |
| Lit. 1 | Comp. Ex. 2 | 200/20/500 | 37 | 2 | 61 | 0.6 | 26 | 16 | 1.0E−4 | None | |
| | | | | | | | | | | described | |
| Patent | Comp. Ex. 3 | 25/50/300 | 10 | 12 | 78 | 0.1 | 6.3 | 0.8 | 6.64E−5 | 800 | nm |

| | | | | | | | | | |
|---|---|---|---|---|---|---|---|---|---|
| Lit. 2 | Comp. Ex. 4 | 15/50/300 | 23 | 47 | 30 | 0.7 | 0.6 | 0.5 | None |
| | Comp. Ex. 5 | 8/50/300 | 14 | 53 | 33 | 0.4 | 0.6 | 0.3 | described |

According to Table 2, the Ni element/Ti element/Al element structure having a film thickness (nm) of 168/25/150 (total film thickness: 343 nm), 118/25/150 (total film thickness: 293 nm), 100/25/150 (total film thickness: 275 nm), 90/25/150 (total film thickness: 265 nm), and 68/25/150 (total film thickness: 243 nm) in the ohmic electrode 18 according to the present invention was designated as Embodiments 1, 2, 3, 4, and 5, respectively, and the Ni element/Ti element/Al element structure having a film thickness (nm) of 18/25/150 was designated as Comparative example 1. The same element combination as that described in Patent Literature 1 and set to a film thickness (nm) of 200/20/500 was designated as Comparative example 2, and the same element combination as that described in Patent Literature 2 and set to a film thickness (nm) of 25/50/300, 15/50/300, and 8/50/300 was designated as Comparative examples 3, 4, and 5, respectively. The characteristic values of contact resistance and surface roughness in Embodiments 1 to 5 are both better than those in Comparative examples 1 to 5.

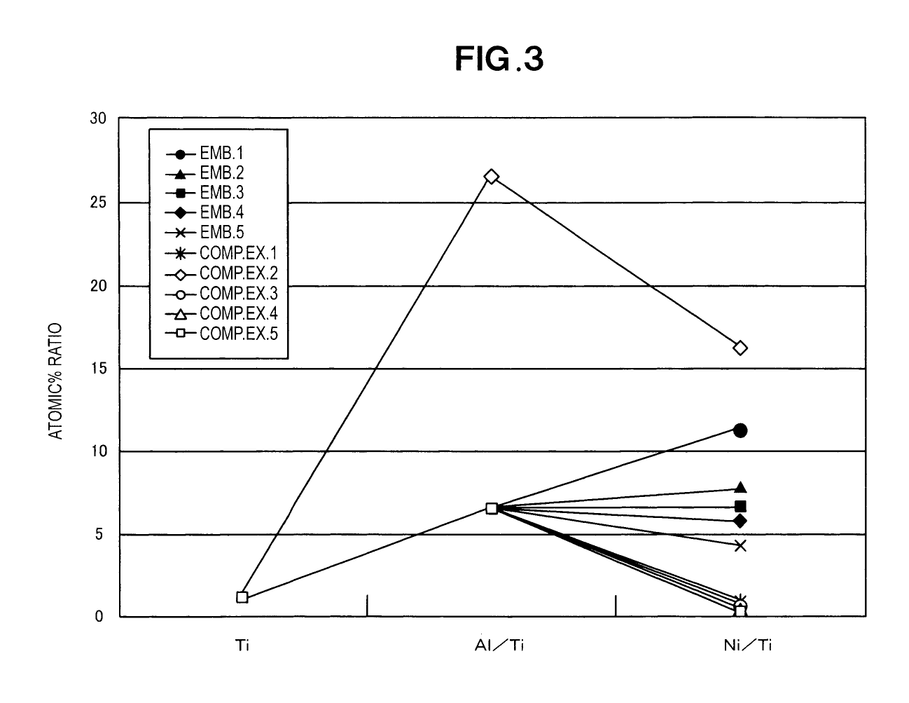

The Al/Ti ratio and Ni/Ti ratio in Embodiments 1 to 5 of the present invention differ from those in Comparative example 2, as seen in FIG. 3. Moreover, the Ni/Ti ratio differs from that in Comparative examples 1, and 3 to 5. It is understood that the contact resistance and the degree of surface unevenness (surface roughness) of the electrodes in Embodiments 1 to 5 can both be made smaller than those of the electrodes in Comparative examples 1 to 5. In particular, the contact resistance and surface roughness are both considered favorable at a value in which the Ni/Ti ratio is within the range of 1 to 11, that is, the Ni/Al ratio is within the range of 0.5 to 1.7.

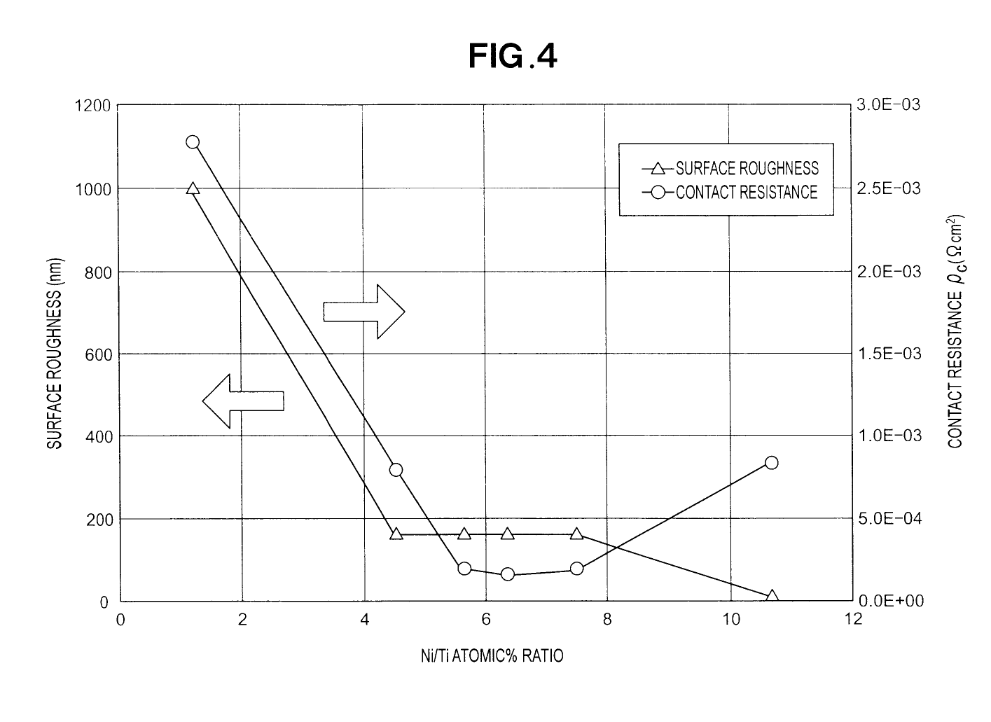

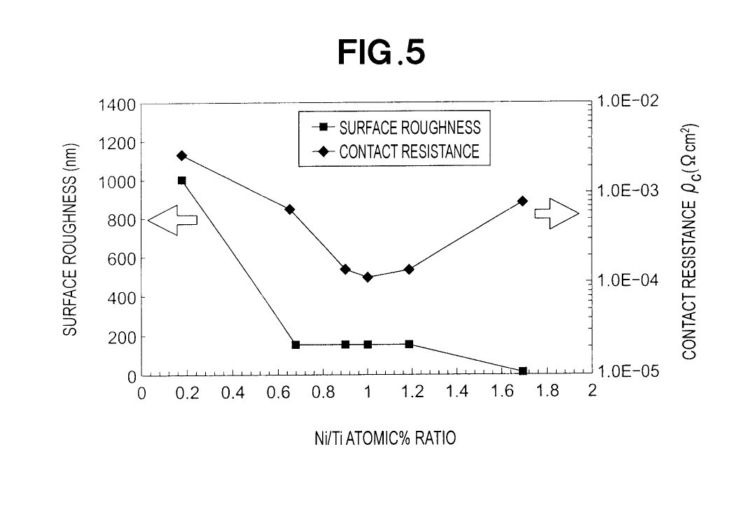

A graph displaying these characteristics is shown in FIGS. 4 and 5. The horizontal axis on the graph in FIG. 4 shows the “Ni/Ti ratio,” the horizontal axis on the graph in FIG. 5 shows the “Ni/Al ratio,” and the vertical axis on both graphs shows the “surface roughness (nm)” and the “contact resistance.”

As a result, the unevenness of the electrode surface (surface roughness) can be kept uniform at a low value of 50 to 150 nm or less while a low contact resistance (1E-4 Ωcm²) can be maintained by properly adjusting the composition ratio of the Ni element to the Ti element in the ohmic electrode 18 formed on the p-type SiC region 13.

In addition, a greater possibility of making the semiconductor element more compact can be achieved by flattening the electrode surface. The variability of the contact resistance can also be suppressed, and the characteristic can be made uniform. Moreover, damage to the interlayer film during bonding can be reduced and other such advantageous effects obtained.

The configuration, shape, size, and arrangement described in the embodiments above provide an outline that allows the present invention to be understood and implemented, and numbers and compositions (materials) of configurations are merely embodiments. Therefore, the present invention is not limited to the embodiments described above, and various modifications can be implemented within a scope that does not depart from the spirit of the claims.

### INDUSTRIAL APPLICABILITY

The present invention may be used for improving both the electrode surface roughness and contact resistance of an ohmic electrode formed on a p-type SiC semiconductor device.

### LEGEND

11 N+-type SiC semiconductor bulk
12 SiC epitaxially grown semiconductor layer
13 P-type region layer (p-type SiC region)
14 Cathode electrode
15 Interlayer film (insulating film)
18 Laminated electrode body (ohmic electrode)
21 Nickel (Ni) layer
22 Titanium (Ti) layer
23 Aluminum (Al) layer

1. A semiconductor device comprising:
a p-type silicon carbide semiconductor region; and
an ohmic electrode including a nickel layer, a titanium layer, and an aluminum layer stacked in a mentioned order on the p-type silicon carbide semiconductor region,
characterized in that the ohmic electrode includes 14 to 47 atomic % of a nickel element, 5 to 12% of a titanium element and 35 to 74% of an aluminum element, and an atomic ratio of the nickel element to the titanium element falls within a range of 1 to 11.

2. The semiconductor device of claim 1, wherein the ohmic electrode has an atomic ratio of the nickel element to the aluminum element of from 0.5 to 1.7 when an atomic ratio of the aluminum element to the titanium element is 6.3.

3. The semiconductor device of claim 1, wherein a laminated film including the nickel layer, the titanium layer, and the aluminum layer in the ohmic electrode has a film thickness of 45 to 690 nm.

4. The semiconductor device of claim 3, wherein the nickel layer, the titanium layer, and the aluminum layer in the ohmic electrode have a film thickness of 10 to 340 nm, 5 to 50 nm, and 30 to 300 nm, respectively.

5. The semiconductor device of claim 1, further comprising another ohmic electrode on a surface of the silicon carbide semiconductor region that is opposite a surface of the silicon carbide semiconductor region that includes the ohmic electrode.

6. A method for manufacturing a semiconductor device having an ohmic electrode that includes a nickel layer, a titanium layer, and an aluminum layer on a p-type silicon carbide semiconductor region, comprising the steps of:
forming the nickel layer on the silicon carbide semiconductor region;
forming the titanium layer on the nickel layer;
forming the aluminum layer on the titanium layer; and
forming the ohmic electrode by heating a laminated electrode body including the nickel layer, the titanium layer, and the aluminum layer at 600 to 850° C.,
wherein the ohmic electrode has an atomic ratio of the nickel element to the titanium element of from 1 to 11.

7. The method of claim 6, wherein the ohmic electrode has an atomic ratio of the nickel element to the aluminum element of from 0.5 to 1.7 when an atomic ratio of the aluminum element to the titanium element is 6.3.

8. The method claim 6, wherein a laminated film including the nickel layer, the titanium layer, and the aluminum layer in the ohmic electrode has a film thickness of 45 to 690 nm.

9. The method of claim 8, wherein the nickel layer, the titanium layer, and the aluminum layer in the ohmic electrode have a film thickness of 10 to 340 nm, 5 to 50 nm, and 30 to 300 nm, respectively.

10. An ohmic electrode comprising a nickel layer, a titanium layer, and an aluminum layer stacked in a mentioned order on a p-type silicon carbide semiconductor region,
characterized in that the electrode includes 14 to 47 atomic % of a nickel element, 5 to 12% of a titanium element, and 35 to 74% of an aluminum element, and an atomic ratio of the nickel element to the titanium element is from 1 to 11.

11. The electrode of claim 10, wherein an atomic ratio of the nickel element to the aluminum element is from 0.5 to 1.7 when an atomic ratio of the aluminum element to the titanium element is 6.3.

12. The electrode of claim 10, wherein a laminated film including the nickel layer, the titanium layer, and the aluminum layer has a film thickness of 45 to 690 nm.

13. The electrode of claim 12, wherein the nickel layer, the titanium layer, and the aluminum layer have a film thickness of 10 to 340 nm, 5 to 50 nm, and 30 to 300 nm, respectively.
